(19) United States
(12) Patent Application Publication
(10) Pub. No.: US 2007/0207606 A1
(43) Pub. Date: Sep. 6, 2007

(54) Method for removing residual flux

(75) Inventors: Chun-Chi Wang, Kaohsiung (TW); Yao-Feng Huang, Kaohsiung (TW); Chih-Hsing Chen, Kaohsiung (TW); Chi-Yu Wang, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/652,085

(22) Filed: Jan. 11, 2007

(30) Foreign Application Priority Data
Mar. 1, 2006 (TW) 95106849

(51) Int. Cl. H01L 21/44

(52) U.S. Cl. 438/613; 438/614; 438/746

(57) ABSTRACT

A method for removing residual flux applied to a wafer process is disclosed by the present invention, the method comprises the steps of: providing a wafer; forming a plurality of bumps on the surface of the wafer; coating flux on the surfaces of the bumps; reflowing the bumps; immersing the wafer in a cleaning solvent; cleaning the wafer by a plasma descum cleaning; rinsing the wafer; and drying the wafer.

### FIELD OF THE INVENTION

The present invention relates to a method for removing residual flux, more particularly to clean the surface of a wafer by a plasma descum method to remove the residual flux on the surface of the wafer.

### BACKGROUND OF THE INVENTION

Due to the innovation of science and technology, the electronic chip tends to be a smaller volume. Those electronic chips have different functions and are usually welded on the board having the electric circuits by solder so as to work properly. Due to the current electronic elements are so tiny, the conventional way is not suitable for them. Hence a new welding method, named as SMT, and the related equipment have been introduced.

While the electronic chip is welded by the SMT, bump or solder is the media role to let such electronic chip be welded on a circuit board. The processes for manufacturing bump are very important, since each step influences the following wafer processes. In general, a plurality of bumps are planted on the wafer firstly. The wafer also has an active surface, a protecting layer and a plurality of contacts disposed thereon. The contacts are exposed on the protecting layer. Then, a photoresist is formed on the active surface and has a plurality of opens, which expose a metal layer under a bump. Continuously filling solder into the open, and processing a heating step for temporarily melting the solder, it is then that the solder is fixed on the contacts. After the solder is filled into all the opens, spreading flux on the surface of the solder. At last, a reflowing step is to joint the solder with the metal layer. Then cleaning the flux and getting rid of the photoresist would accomplish the manufacturing processes for the bump, and then continuing the wafer processes.

While in the stage of welding the bump or the solder, the flux is for cleaning the oxide or oil sludge of the bump on the chip or the solder on the base board to have a good welding effect. Due to the flux affects the digital signal transmission of the electric elements, therefore the cleaning process may be engaged more frequently to dissolve and clean the flux.

Referring to the FIG. 1, which is a schematic view of removing residual flux by cleaning solvent in prior arts. There is a plurality of bumps 11 in a wafer 10, and residual flux 12 is around the bumps 11.

It is to be noted that non-water-based cleaning solvent is selected while cleaning the flux, wherein the cleaning solvent is composited by two of the follows: MeOCH₂CH₂OH (concentration in 60 to 100%), cycloaminium (concentration in 10 to 30%), MeOCH₂CH₂OH, and KOH (concentration in 1 to 5%). Usually, after cleaning the surface of the wafer with the solvent described above, it should leave no residual flux since the roughness of the surface of the wafer is under 0.4 μm. The particles of the flux 12 would not stick on the wafer 10. However, the roughness of the surface is greater than 0.4 μm, the particles of the flux 12 would stick on the surface of the wafer 10. Hence the solvent could not remove all the flux.

Therefore, how to resolve the drawbacks of the cleaning solvent that fail to completely remove the flux particles and to avoid the residual flux left on the surface of the wafer to influence the wafer processes is an important issue in the field.

### SUMMARY OF THE INVENTION

The objective of the present invention is to provide a method for removing residual flux applied to a wafer process, wherein the characteristic is to clean the surface of the wafer by plasma descum to remove the residual flux on the surface of the wafer.

In accordance with the present invention, the cleaning method for removing the residual flux comprises the steps of: providing a wafer, which comprises a plurality of pads and forms an under bump metallurgy layer on each pad; coating a photoresist pattern on the surface of the wafer to expose the under bump metallurgy layer and print a solder layer on the under bump metallurgy layer for first pre-reflowing the solder; after removing the photoresist pattern, coating flux on these soldered surfaces; continuing the second reflowing and forming a bump; for cleaning the wafer, putting the wafer into the clean solvent; then the wafer and bumps being cleaned with plasma descum; after the plasma descum, the wafer being rinsed by high-pressure de-ionized water; and continuously to dry the wafer.

In the preferred embodiment, the roughness of the surface of the wafer is greater than 0.435 μm. The plasma is used to produce free radical to react with compound for removing the flux. And a centrifugal device or a roast device is used for drying the wafer.

### BRIEF DESCRIPTION OF THE DRAWINGS

Other features and advantages of this invention will become more apparent in the following detailed description of the preferred embodiments of this invention, with reference to the accompanying drawings, in which:

FIG. 1 is a schematic view of removing residual flux by cleaning solvent in prior arts;

FIG. 2 is a flow chart of a method for removing the residual flux by a plasma descum of the present invention; and

FIG. 3 is a picture of removing the residual flux by the plasma descum of the present invention.

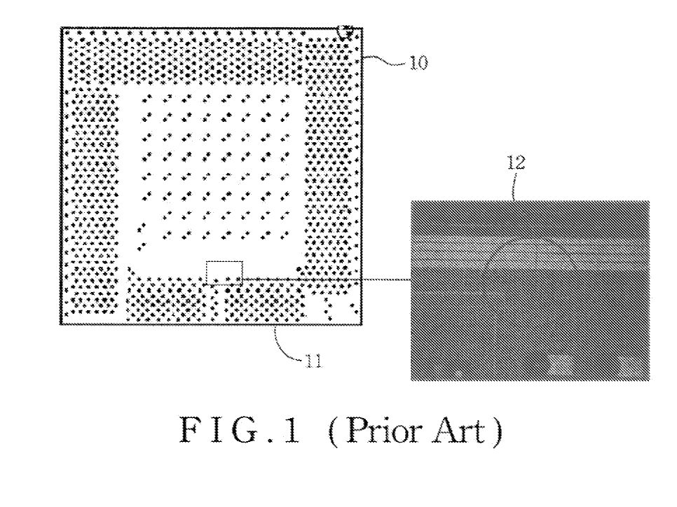

### DETAILED DESCRIPTIONS OF THE PREFERRED EMBODIMENT

The present invention provides a method for removing residual flux applied to a wafer process, wherein the characteristic is that some residual flux may remain on the surface of the wafer after cleaning with cleaning solvent, then the residual flux on the surface of the wafer is cleaned by plasma descum.

The present Flip Chip processes usually comprise: the bump forming before the fabrication, the wafer sawing, the grain bonding, the reflowing, the cleaning, the underfilling, the glue curing, etc. The bump usually includes the solder bump, the gold bump, the conductive polymer bump, the macromolecule bump, etc. The solder bump is the most popular.

When welding the bump or the solder on the chip, it often uses the flux to clean the oxide or oil sludge on the bump of the chip or the solder on the base board to get a better welding effect. Due to the flux is divided into two kinds of water soluble and oil soluble, during the Flip Chip process, a heating step causes flux or oil sludge leakage, which will interference the digital transmission of the electric elements. Therefore, the flux or oil sludge should be removed.

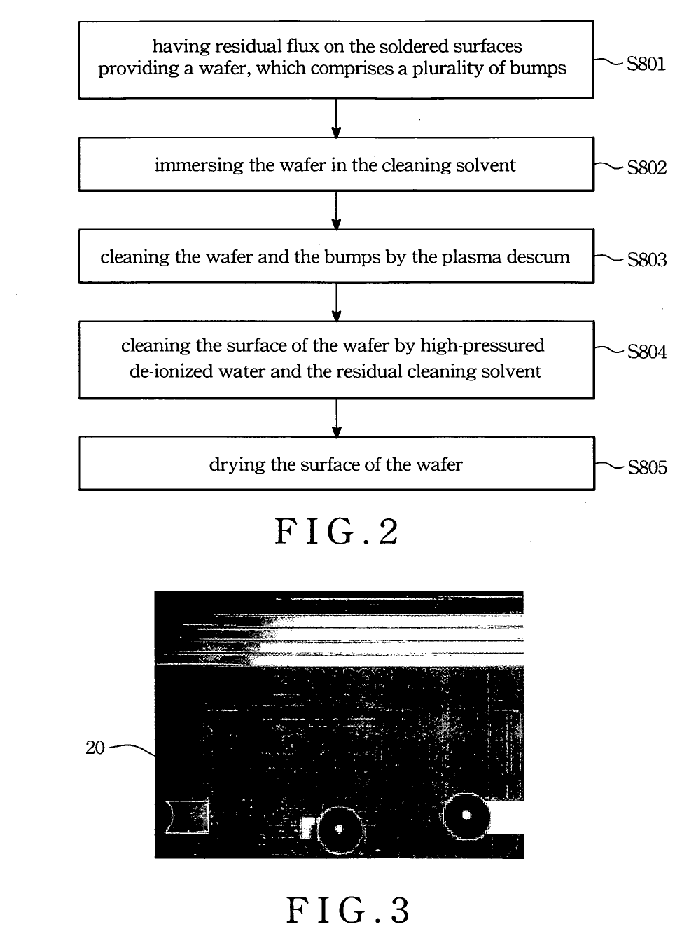

Please refer to FIG. 2, which is a flow chart of a method for removing the residual flux by plasma descum of the present invention. The method comprises the steps of:

S801: providing a wafer, which comprises a plurality of pad and forms an under bump metallurgy layer on each pad; coating photoresist pattern on the surface of the wafer to expose the under bump metallurgy layer and print the solder on the under bump metallurgy layer for first pre-reflowing of the solder; after removing the photoresist pattern, coating flux on these soldered surfaces; continuing the second re-flowing and forming the bump;

after removing the photoresist, it coating flux on the soldered surfaces, and using the tin-lead bump for a etching mask; then heating the tin-lead bump to the liquid line of the tin-lead alloy in order to engage a second-re-flowing to complete the tin-lead bump processes;

wherein, as described above, the flux is spread on the wafer and the solder during the processes of heating and soldering, the flux is not only for fixing the bumps temporarily, but also active the oxide on the surfaces of the tin-lead bumps so as to achieve a better effect, during the heating process, the flux would remove the oxide layer on the surfaces of the tin-lead bumps so as to gain polished and clean surfaces, which leave for further processes, because it is easy to over-coking during heating the flux, cleaning the surfaces of the wafer and the bumps may be harder;

S802: to remove the residual flux, immersing the wafer in the cleaning solvent, which is composted by one of the follows: MeOCH₂CH₂OH and cycloaminium, MeOCH₂CH₂OH and KOH, cycloaminium and KOH, and MeOCH₂CH₂OH, cycloaminium, and KOH. The immersing time is about 10 minutes; the flux mentioned above contains the halogens and other chemical composition; after removing the halogens by the clean solvent, the other chemical composition of the flux still remain thereon;

S803: to clean the wafer and the bumps by the plasma descum again, the plasma descum would produce free radical by the vapor aroused, after polarized the vapor to small molecules, hitting the chemical composition of the flux, then the remaining composition of the flux being removed;

S804: to clean the surface of the wafer by high-pressured de-ionized water and the residual cleaning solvent, the de-ionized water is circulated and rinses the surface of the wafer at high-pressure, and the temperature is kept under 25° C. by a cooling system; and

S805: to dry the surface of the wafer by using a centrifugal device, a roast device, or a spin rinse dryer (SRD), then placing the wafer in the above device and making the de-ionized water left on the surface of the wafer to fly off for achieving the drying;

continuing to proceed the jointed or other processes of the wafer and substrates;

Referring to FIG. 3, which is a picture of removing the residual flux by the plasma descum of the present invention. The present invention has the merits as following points:

1. The conventional method for cleaning particles, metal, and organic compound would base on wet chemical solvent. It consumes a large amount of de-ionized water and chemical compounds. The de-ionized water and high-purified chemicals are very expensive for the wet cleaning methods. The shortcomings also induce the issues of environment-protection. The current invention removes the flux with the plasma descum, which requires no chemicals, but adopting molecule hitting and leaving no contamination problems.

2. The current invention uses the plasma descum to remove the remained flux. Neither ethylene nor ethylene ether leaves on the surface of the wafer and the bumps so as to avoid the etching problem and promote the reliability and the quality of the chips.

3. The roughness of the surface of the wafer is greater than 0.4 μm (the coarse intensity is 0.435 μm in the embodiment). After the plasma descum cleaning the wafer, it can completely remove the remained flux.

4. In the convention method to clean the flux of the wafer, the process of immersing the wafer into the cleaning solvent is repeated for removing the flux. Due to the cleaning solvent cannot completely remove the flux, the chemicals will remain on the surface of the wafer. The plasma descum of the present invention can fully remove the residual flux, and it can save more manpower.

Although this invention has been disclosed and illustrated with reference to particular embodiments, the principles involved are susceptible for use in numerous other embodiments that, will be apparent to persons skilled in the art. This invention is, therefore, to be limited only as indicated by the scope of the appended claims.

What is claimed is:

1. A method for removing residual flux applied to a wafer process, the method comprising the steps of:
providing a wafer;
forming a plurality of bumps on the surface of the wafer;
coating flux on the surfaces of the bumps;
reflowing the bumps;
immersing the wafer in a cleaning solvent;
cleaning the wafer by plasma descum;
rinsing the wafer; and
drying the wafer.

2. The method for removing the residual flux according to claim 1 further comprising the step of forming an under bump metallurgy layer before the step of forming the plurality of bumps on the surface of the wafer.

3. The method for removing the residual flux according to claim 2, wherein the step of forming the plurality of bumps on the surface of the wafer further comprises the step of forming a photoresist pattern on the surface of the wafer to expose the under bump metallurgy layer.

4. The method for removing the residual flux according to claim 3, wherein the step of forming the plurality of bumps on the surface of the wafer further comprises the step of printing solder on the under bump metallurgy layer.

5. The method for removing the residual flux according to claim 4, further comprising the step of removing the photoresist pattern.

6. The method for removing the residual flux according to claim 1, further comprising a pre-reflowing step after the step of coating flux on the surfaces of the bumps.

7. The method for removing the residual flux according to claim 1, wherein the cleaning solvent is selected from one of the follows: the composition of MeOCH₂CH₂OH and cycloaminium, MeOCH₂CH₂OH and KOH, cycloaminium and KOH, and MeOCH₂CH₂OH, cycloaminium, and KOH.

8. The method for removing the residual flux according to claim 1, wherein the roughness of the surface of the wafer is greater than 0.4 μm.

9. The method for removing the residual flux according to claim 1, wherein the step of rinsing the wafer further comprises the step of using high-pressured de-ionized water to rinse the surface of the wafer, and the temperature of the de-ionized water is under 25° C.

10. The method for removing the residual flux according to claim 1, wherein the step of cleaning the wafer by the plasma descum further comprises using the reaction of free radical and compound produced by plasma to remove the flux.

11. The method for removing the residual flux according to claim 1, wherein the step of drying the wafer uses the device selected from the group of: a centrifugal device and a roast device.
